(19) United States
(12) Patent Application Publication
(10) Pub. No.: US 2026/0318287 A1
(43) Pub. Date: Oct. 15, 2026

(54) ACTUATOR ASSEMBLY AND METHOD FOR OPERATING SAME

(71) Applicant: TECHNISCHE UNIVERSITÄT BERLIN, Berlin (DE)

(72) Inventors: Robert COURANT, Berlin (DE); Jürgen MAAS, Detmold (DE)

(73) Assignee: TECHNISCHE UNIVERSITÄT BERLIN, Berlin (DE)

(21) Appl. No.: 19/109,413

(22) PCT Filed: Aug. 31, 2023
(86) PCT No.: PCT/EP2023/073903

§ 371 Date: Mar. 6, 2025

(30) Foreign Application Priority Data
Sep. 9, 2022 (EP) 22194794.8

(51) Int. Cl. F03G 7/06

(52) U.S. Cl. CPC F03G 7/06147; F03G 7/062; F03G 7/066

(57) ABSTRACT

The invention relates to an actuator assembly, having an actuator element (1), a first flux generating device (5) for generating a magnetic flux, a second flux generating device (6) for generating a magnetic flux, a control device (15) and a pole shoe element (11, 12, 13, 14). The actuator element (1) has a magnetic shape memory alloy and a region of the actuator element (1) has a first length in a first direction, if the region is penetrated by a magnetic field in the first direction, and has a second length, different from the first length, in the first direction, if the region is penetrated by a magnetic field in a second direction that is perpendicular to the first direction. The control device (15) is configured to control the first flux generating device (5) and/or the second flux generating device (6) according to a first operating state and a second operating state, such that in the first operating state the actuator element (1) is penetrated by a first magnetic flux (3) in the first direction, and in the second operating state the actuator element (1) is penetrated by a second magnetic flux (4) in the second direction. The pole shoe element (11, 12, 13, 14) is configured to guide the first magnetic flux (3) in the first direction through the actuator element (1) or to guide the second magnetic flux (4) in the second direction through the actuator element (1). The pole shoe element (11, 12, 13, 14) is provided as a magnetic anisotropic pole shoe element. The invention also relates to a method for operating an actuator assembly. (FIG. 4b)

The invention relates to an actuator assembly and a method for operating same.

### BACKGROUND

Magnetic shape memory alloys (MSMA) are special shape memory alloys which, in addition to the thermal shape memory effect, also comprise a magnetic shape memory effect. In this case, a change in the magnetic orientation of the magnetic elementary cells of the shape memory alloy is accompanied by a deformation in which a change in length occurs (as viewed for a spatial direction).

The reorientation can be caused by external forces by means of compression or elongation. In this case, the material has an internal friction which requires overcoming a force or stress limit for the reorientation. This phenomenon is also known under the designation “twinning stress”. In addition to this twinning stress, MSMA also exhibit the named magnetic shape memory effect. This involves a sufficiently large magnetic field causing a contraction (tension) in the field direction and, correspondingly perpendicularly thereto, an elongation (pressure), wherein both force effects can be utilized.

In contrast to purely thermal shape memory alloys, MSMA with the same stroke have significantly faster reaction times (a few ms compared to s). Compared to piezoelectric materials, a significantly higher stroke can be achieved. In the case of a suitable evaluation, self-sensing can be utilized for cost reduction in the sensor system.

Due to the material-inherent twinning stress, magnetic shape memory alloys are suitable for linear actuators which can hold a set position without energy supply. This is of interest, for example, for applications with specific safety requirements in the case of energy outage. The technology combines a large holding force, as can also be achieved in the case of actuator systems with a self-locking transmission, with a high dynamic range, as exhibited by electro-dynamic actuators. Such characteristics are of interest for various actuating devices in automation and vehicle engineering, for example as grippers in robotics, but also for valves in pneumatic and hydraulic systems.

Known MSMA actuators usually operate as pure push or pull actuators against a restoring force. This restoring force must exceed the material-inherent twinning stresses, so that the actuator can be deformed back into the original position without excitation. Such an actuator device is known from document DE 10 2005 038 891 A1. In such a configuration, the twinning stress is to be considered as a pure loss. In order to be able to hold a position outside the rest position, a magnetic field must be applied permanently. Therefore, the alloys and the actuators produced therefrom (usually in the form of sticks) are optimized as far as possible to low twinning stresses.

In contrast to this, multistable concepts explicitly use the twinning stress for a passive holding force in more than one position. According to one concept, only this holding force is used, but not the magnetic shape memory effect. For example, the actuation is realized by a voice coil actuator and an MSMA element applies only a passive holding force. This must then be additionally overcome during each actuation.

A further concept uses the magnetic shape memory effect in one direction and provides a restoring via the application of a mechanical force. As a result of the combination of two such actuators, a push-push actuator can be constructed, in which two MSMA actuators are arranged opposite one another with mutually opposite actuation directions. If the one MSMA element is excited, a central tap is displaced in the actuation direction of the one MSMA element. If the other MSMA element is excited, the tap moves in the opposite direction. In this case, one MSMA element is actively used, while the twinning stress of the other MSMA element must be passively overcome by the force applied by the active MSMA element. For such a construction, independent excitation systems are necessary for the MSMA elements, of which only one is always in use.

Finally, concepts exist which use both the holding force and the magnetic shape memory effect in both directions. In this case, perpendicular fields must be able to be imposed on an MSMA element in order to enable the deformation in both directions. Such a concept combines the multistable holding force with the actuator use of the full material. The design of the excitation system for such actuators is complex. For example, independent coils or coil sets can be provided for the excitation directions, in which case only one coil set is always actively used at a given time.

From document U.S. Pat. No. 10,581,345 B2 , a concept for the operation of an MSMA actuator with four coils is known. In this case, the four coils form two groups of two coils connected in series with one another. The groups are arranged crosswise around the MSMA element. Flux-guiding elements are designed in such a way that, as a result of the superposition of the magnetic fields generated, with the same current supply direction in the two groups, the MSMA element is penetrated by a magnetic flux in a first direction and, with the opposite current supply direction in the two groups, the MSMA element is penetrated by a magnetic flux in a second direction, wherein the second direction is perpendicular to the first direction.

### SUMMARY

The object of the invention is to provide improved technologies for actuator assemblies with magnetic shape memory alloys which, in particular, enable a more efficient and/or more targeted flux guidance.

In order to achieve the object, an actuator assembly according to independent claim 1 and a method for operating an actuator assembly are provided. Embodiments are specified in the appended set of claims in dependent claims.

According to one aspect, an actuator assembly is provided with an actuator element, a first flux generating device for generating a magnetic flux, a second flux generating device for generating a magnetic flux, a control device and a pole shoe element. The actuator element comprises a magnetic shape memory alloy. A region of the actuator element has a first length in a first direction, if the region is penetrated by a magnetic field in the first direction, and has a second length in the first direction, different from the first length, if the region is penetrated by a magnetic field in a second direction that is perpendicular to the first direction. The control device is configured to control the first flux generating device and/or the second flux generating device according to a first operating state and a second operating state, such that in the first operating state the actuator element is penetrated by a first magnetic flux in the first direction, and in the second operating state the actuator element is penetrated by a second magnetic flux in the second direction. The pole shoe element is configured to guide the first magnetic flux in the first direction through the actuator element or is configured to guide the second magnetic flux in the second direction through the actuator element. Here, the pole shoe element is provided as a magnetically anisotropic pole shoe element.

Further, a method for operating an actuator assembly is provided. The method comprises the steps of providing the actuator assembly according to the disclosure, controlling the first flux generating device and/or the second flux generating device for generating the first magnetic flux penetrating the actuator element in the first direction, such that the actuator element assumes a first shape, and controlling the first flux generating device and/or the second flux generating device for generating the second magnetic flux penetrating the actuator element in the second direction, such that the actuator element assumes a second shape which is different from the first shape.

A magnetically anisotropic pole shoe element in the sense of the disclosure has a higher magnetic resistance in one direction than in another direction. In particular, a pole shoe element is a magnetically anisotropic pole shoe element if the (geometry-independent) homogenized initial permeability of the pole shoe element is greater in the one direction at least by the factor 250 than in the other direction, wherein the homogenized initial permeability is the average relative permeability (or permeability number) of the pole shoe element in the respective direction at low flux densities, i.e. without saturation. As explained in detail below, the pole shoe element can be formed with a laminate, wherein in this case the homogenized initial permeability of the pole shoe element in the respective direction is determined for a series connection or parallel connection of the individual materials. By using a magnetically anisotropic pole shoe element, a magnetic flux through the pole shoe element in an undesired direction can be reduced or prevented. In particular, a magnetically anisotropic pole shoe element which is configured to guide the first magnetic flux in the first direction through the actuator element can have a smaller magnetic resistance in the first direction than in the second direction. Correspondingly, a magnetically anisotropic pole shoe element which is configured to guide the second magnetic flux in the second direction through the actuator element can have a smaller magnetic resistance in the second direction than in the first direction. Here, a magnetic flux bypassing the actuator element through the pole shoe element can then be reduced or prevented in the direction of the larger magnetic resistance of the pole shoe element.

The pole shoe element can be formed with a laminate which consists of an arrangement of a plurality of layers, wherein the plurality of layers comprise first layers of a first material and second layers of a second material. In this case, in the arrangement of a plurality of layers, first layers and second layers are arranged alternately one above the other, wherein the first material has a first permeability number (also referred to as relative permeability) and the second material has a second permeability number which is different from the first permeability number. As a result, it can be achieved in particular that the pole shoe element has a smaller magnetic resistance in the direction of extent of the layers than transversely with respect to the direction of extent of the layers, since the magnetic flux can propagate unhindered through the layers with the higher permeability number in the direction of extent of the layers, while the magnetic flux must pass through the layers with the lower permeability number transversely with respect to the direction of extent. The material of the first and of the second material with the lower permeability number can be a non-magnetic material. For example, the pole shoe element can be formed with a laminate of soft iron and epoxy resin layers.

In the laminate, the layers can be connected to one another, as is known per se from the prior art in various embodiments for laminates, for example by an adhesive connection or thermal connection techniques.

In an alternative refinement, in the laminate, the layers with the lower permeability number can be formed by air, another gas or gas mixture, or by a vacuum. In this case, the layers are not connected to one another and the laminate of the pole shoe element can be provided in particular from a material with a high permeability number which is formed with slots and/or other cutouts.

The pole shoe element can be formed with a magnetically anisotropic material. Here, the pole shoe element comprises at least one material which is intrinsically magnetically anisotropic, i.e. has a different magnetic permeability in one direction than in another direction. The magnetic anisotropy of the pole shoe element can be achieved solely or substantially by using a magnetically anisotropic material, in particular if the material used has a highly pronounced magnetic anisotropy. Here, a highly pronounced magnetic anisotropy of a material is provided in particular if a permeability number of the material is greater in one direction at least by the factor 20 than in the other direction. Here, a magnetically anisotropic pole shoe element with a homogenized initial permeability which is greater by at least the factor 250 in the one direction than in the other direction can be achieved by a correspondingly large factor between the direction-dependent permeability numbers of the magnetically anisotropic material or can alternatively be achieved by additional measures, for example by a suitable geometry of the pole shoe element and/or in that the pole shoe element is formed with a laminate. In particular, when the pole shoe element is formed with a laminate, the first material and/or the second material can be a magnetically anisotropic material. In this way, an intrinsic magnetic anisotropy of the first and/or of the second material can be reinforced by the arrangement of a plurality of layers in the laminate for the pole shoe element in its entirety.

A flux guiding element which is assigned to the pole shoe element and is formed with a wedge shape can be provided. Here, the flux guiding element is arranged in such a way that a magnetic resistance of the arrangement of pole shoe element and assigned flux guiding element in the direction of lower magnetic resistance of the pole shoe element is higher in edge regions of the arrangement of pole shoe element and assigned flux guiding element than in a central region of the arrangement of pole shoe element and assigned flux guiding element. Here, the edge regions are regions which are formed opposite one another along the direction of higher magnetic resistance of the pole shoe element at edges of the pole shoe element. The central region lies between the edge regions along the direction of higher magnetic resistance of the pole shoe element. The wedge shape of the flux guiding element can be formed in such a way and the flux guiding element can be arranged in such a way that a larger air gap is formed between the pole shoe element and the flux guiding element in the edge regions than in the central region, wherein the flux guiding element can be arranged in the central region with an air gap with respect to the pole shoe element or directly bearing against the pole shoe element or connected to the latter.

The actuator arrangement can be formed with two pole shoe elements which are arranged along the first direction on opposite sides of the actuator element and are each configured to guide the first magnetic flux in the first direction through the actuator element, wherein the two pole shoe elements are provided as magnetically anisotropic pole shoe elements. For this purpose, the two pole shoe elements can be arranged in particular in such a way that they have a smaller magnetic resistance in the first direction than in the second direction. In this way, an effective guidance of the magnetic flux in the first direction through the actuator element can be ensured by means of the two pole shoe elements in the first operating state, while in the second operating state a magnetic flux through the two pole shoe elements in the second direction is reduced or prevented by bypassing the actuator element.

Two further pole shoe elements can be provided which are arranged along the second direction on opposite sides of the actuator element and are each configured to guide the second magnetic flux in the second direction through the actuator element. In this way, an effective guidance of the magnetic flux in the second direction through the actuator element can be ensured by means of the two further pole shoe elements in the second operating state.

The two further pole shoe elements can be provided as magnetically anisotropic pole shoe elements. Here, the two further pole shoe elements can be arranged in particular in such a way that they have a smaller magnetic resistance in the second direction than in the first direction. In this way, an effective guidance of the magnetic flux in the second direction through the actuator element can then be ensured by means of the two further pole shoe elements in the second operating state, while in the first operating state a magnetic flux through the two further pole shoe elements in the first direction is reduced or prevented by bypassing the actuator element.

In alternative refinements, the two further pole shoe elements are not provided as magnetically anisotropic pole shoe elements. This can be provided in particular if, on account of the refinement of the actuator arrangement in the first operating state, a magnetic flux through the two further pole shoe elements in the first direction is not to be expected or is not to be expected to an extent which significantly reduces the efficiency of the actuator arrangement by bypassing the actuator element.

In the various embodiments, a wedge-shaped flux guiding element can be assigned to each or all of the magnetically anisotropic pole shoe elements, wherein the above embodiments with respect to the flux guiding element apply correspondingly.

The actuator element can be formed as a rod-shaped actuator element which has a greater extent along a longitudinal direction which runs in the second direction than in a transverse direction which runs in the first direction. A rod-shaped actuator element can have in particular an aspect ratio between the extent along the longitudinal direction and the extent along the transverse direction of greater than or equal to 3:1. In particular in connection with a rod-shaped actuator element with longitudinal direction along the second direction, an arrangement with two pole shoe elements can be provided which are arranged along the first direction on opposite sides of the actuator element and are each configured to guide the first magnetic flux in the first direction through the actuator element, wherein the two pole shoe elements are provided as magnetically anisotropic pole shoe elements and are arranged in such a way that they have a smaller magnetic resistance in the first direction than in the second direction. In this way, an effective guidance of the magnetic flux in the transverse direction through the rod-shaped actuator element can then be ensured by means of the two pole shoe elements in the first operating state, while in the second operating state a magnetic flux through the two pole shoe elements in the longitudinal direction is reduced or prevented by bypassing the actuator element. This can be advantageous in particular if, on account of the smaller cross section of the actuator element in the longitudinal direction and the length of the actuator element in the longitudinal direction, a tendency is to be established that the magnetic flux in the second operating state runs significantly over the two pole shoe elements in the second direction and therefore the magnetic flux in the second direction is reduced in the actuator element. In this case, the loss of magnetic flux effective in the actuator element is reduced by means of the pole shoe elements with increased magnetic resistance in the second direction (longitudinal direction of the actuator element). While, in embodiments, two further pole shoe elements according to the preceding embodiments can additionally be provided as magnetically anisotropic pole shoe elements, in alternative embodiments, in the case of a large aspect ratio between longitudinal direction and transverse direction of the actuator element, this can be dispensed with, in particular if it is not to be expected that the magnetic flux in the first operating state runs significantly over the two further pole shoe elements in the first direction and therefore the magnetic flux in the first direction is reduced in the actuator element.

In general, any desired suitable cross section can be provided for a rod-shaped actuator element. For example, a rod-shaped actuator element according to the disclosure can have a rectangular, for example square, cross section, a round, approximately circular or oval, cross section or a polygonal, approximately triangular, hexagonal or trapezoidal, cross section.

In alternative embodiments, the actuator element can be formed with a different shape than a rod shape. For example, the actuator element can be a cube-shaped actuator element.

In further alternative embodiments, any desired shape suitable for a given application can be provided for the actuator element. For example, an actuator element can be formed as any desired polyhedron or with a curved shape.

According to one embodiment, it can be provided that the first and the second flux generating device are each formed with a flux generating element which generate magnetic fields which cross one another and run obliquely with respect to the first and the second direction. In this case, a superposition of the magnetic fields generated by the first and the second flux generating device leads, in the first operating state, to the first magnetic flux in the first direction and, in the second operating state, to the second magnetic flux in the second direction. In particular, it can be provided that the first or the second flux generating device is formed with a coil as flux generating element and the first and the second operating state differ in the current supply direction of this coil, as a result of which the direction of the magnetic field generated is reversed and the superposition of the magnetic fields running obliquely with respect to the first and the second direction correspondingly produces the first or second magnetic flux according to the first or the second operating state.

The first flux generating device and the second flux generating device can each comprise at least two flux generating elements. Here, it can be provided in particular that the flux generating elements are arranged in a rectangular, in particular square, arrangement in such a way that the flux generating elements of the first flux generating device lie diagonally opposite one another in the rectangular (square) arrangement and the flux generating elements of the second flux generating device lie diagonally opposite one another in the rectangular (square) arrangement.

The actuator element can be arranged centrally with respect to the arrangement of the two flux generating elements of the first flux generating device and of the two flux generating elements of the second flux generating device. Alternatively, the actuator element can be arranged eccentrically with respect to the arrangement of the flux generating elements in at least one spatial direction. In this case, the magnetic flux generated by the flux generating elements can be guided to and through the actuator element by means of the pole shoe element and/or by means of one or more further pole shoe elements according to the first or the second operating state. In a preferred embodiment, the actuator element can be arranged offset with respect to a plane spanned by the flux generating elements arranged in a rectangular (in particular square) arrangement. With such an assembly, a particularly space-saving actuator assembly can be provided.

The first flux generating device and the second flux generating device can each be formed with at least two coils as flux generating elements. The at least two coils of the first flux generating device can be connected in series and the at least two coils of the second flux generating device can be connected in series. In such an embodiment, the switching between the first and the second operating state can then take place in that the current supply direction of the coils of the first flux generating device is reversed by means of the control device, while the current supply direction of the coils of the second flux generating device remains unchanged, or vice versa. In this case, the magnetic flux generated by the flux generating elements can be guided to and through the actuator element by means of the pole shoe element and/or by means of one or more further pole shoe elements according to the first or the second operating state, wherein the direction of the current in the operating states leads to a different superposition of the fields generated by means of the coils and thus to a magnetic flux in the first direction through the actuator element or to a magnetic flux in the second direction through the actuator element. This can be provided in particular for an embodiment in which the flux generating elements are arranged in a rectangular (square) assembly in such a way that the flux generating elements of the first flux generating device lie diagonally opposite one another in the rectangular assembly and the flux generating elements of the second flux generating device lie diagonally opposite one another in the rectangular assembly.

The first flux generating device can be formed with at least two coils as flux generating elements, while the second flux generating device is formed with at least two permanent magnets as flux generating elements. In such an embodiment, it is provided in particular that a magnetic flux with constant orientation is provided by the second flux generating device by means of the at least two permanent magnets, and the switching between the first and the second operating state can take place in that the current supply direction of the coils of the first flux generating device is reversed by means of the control device. In this case, the magnetic flux generated by the flux generating elements can be guided to and through the actuator element by means of the pole shoe element and/or by means of one or more further pole shoe elements according to the first or the second operating state, wherein the current supply direction of the coils of the first flux generating device leads, in the operating states, to a different superposition of the fields generated by means of the coils and thus to a magnetic flux in the first direction through the actuator element or to a magnetic flux in the second direction through the actuator element. This can be provided in particular for an embodiment in which the flux generating elements are arranged in a rectangular (in particular square) assembly in such a way that the flux generating elements of the first flux generating device lie diagonally opposite one another in the rectangular assembly and the flux generating elements of the second flux generating device lie diagonally opposite one another in the rectangular assembly.

In an alternative embodiment, the first flux generating device and the second flux generating device can each comprise a flux generating element which is formed with a coil, wherein the first flux generating device is configured to generate the first magnetic flux and the second flux generating device is configured to generate the second magnetic flux. Independent coils can thus be provided, wherein the magnetic flux generated by means of one of the flux generating devices serves directly for establishing the first or the second operating state. In this case, it can be provided in particular that the control device activates the first flux generating device and deactivates the second flux generating device in order to set the first operating state and deactivates the first flux generating device and activates the second flux generating device in order to set the second operating state, or vice versa. In such an embodiment, the setting of the first and second operating state can take place in particular without this being based on a superposition of the magnetic fluxes generated by means of the first and the second flux generating device.

In a further alternative embodiment, the first flux generating device can be formed with a coil as flux generating element, while the second flux generating device is formed with a permanent magnet as flux generating element, wherein the first flux generating device is configured to generate the first magnetic flux and the second flux generating device is configured to generate the second magnetic flux. In such an embodiment, the actuator arrangement assumes the second operating state in the rest state, i.e. without current supply to the coil of the first flux generating device, due to the effect of the permanent magnet of the second flux generating device. In order to generate the first operating state, current is supplied to the coil of the first flux generating device, wherein the magnetic flux generated by means of the coil is so great that it superposes the flux generated by the permanent magnet of the second flux generating device in the actuator element such that the first magnetic flux is established in the actuator element. In this context, it is understood that, by means of such a superposition, no rotation of the resulting magnetic flux in the actuator element by exactly 90 degrees can already be achieved computationally. In this respect, according to the disclosure, a first magnetic flux which penetrates the actuator element in the first direction and a second magnetic flux which penetrates the actuator element in the second direction are to be understood as meaning fluxes whose direction comes close enough to the first or the second direction in order to achieve the assumption of the first or the second length by the region of the actuator element. A bias of the actuator arrangement toward the second operating state is thus achieved.

Alternatively, the second flux generating device can be formed with a coil as flux generating element, while the first flux generating device is formed with a permanent magnet as flux generating element, wherein the first flux generating device is configured to generate the first magnetic flux and the second flux generating device is configured to generate the second magnetic flux. In this case, the above embodiments with respect to a first flux generating device formed with a coil and a second flux generating device formed with a permanent magnet with the corresponding adaptations apply, such that a bias of the actuator arrangement toward the first operating state is achieved.

A biasing device which is assigned to the first flux generating device or the second flux generating device and is configured to provide, as magnetic bias, a magnetic flux corresponding to an operation of the first flux generating device or the second flux generating device when the first flux generating device and the second flux generating device are not in operation can be provided. In this case, the biasing device is provided in addition to the flux generating devices. For example, the biasing device can be formed with one or more permanent magnets which are arranged in a magnetic circuit of the actuator assembly such that they provide a magnetic flux corresponding to an operation of the first flux generating device or the second flux generating device.

A direction of the magnetic bias provided by means of the biasing device can be adjustable by means of the first flux generating device and/or the second flux generating device. For example, the biasing device can be formed with one or more elements composed of a magnetically semi-hard material which are arranged in a magnetic circuit of the actuator assembly such that they assume a magnetization corresponding to the relevant operating state during an operation of the actuator assembly in the first or the second operating state and maintain the relevant operating state when the first flux generating device and the second flux generating device are not in operation. If the actuator assembly is subsequently actuated in accordance with the respective other operating state, the polarity of the elements composed of the magnetically semi-hard material is reversed such that they then maintain the other operating state when the first flux generating device and the second flux generating device are not in operation.

In embodiments with a biasing device, it can be provided that the bias is overcome by means of the flux generating device to which the biasing device is assigned, by means of the flux generating device to which the biasing device is not assigned, or by means of the two flux generating devices in order to achieve an operating state which does not correspond to the bias achieved by means of the biasing device. For example, the biasing device can be assigned to a coil of the respective flux generating device and provide a magnetic flux corresponding to an operation of the coil with a specific current supply direction. In this case, an operation of the respective coil with the reverse current supply direction can be provided in order to overcome the bias and achieve a desired operating state of the actuator assembly.

A further biasing device can be provided, wherein the biasing device is then assigned to the first flux generating device and the further biasing device is assigned to the second flux generating device. For the further biasing device, the embodiments explained above in connection with the biasing device can be provided accordingly. In particular in embodiments in which the first operating state and the second operating state are achieved by a superposition of the magnetic fluxes generated by means of the first flux generating device and the second flux generating device, a bias toward the first or the second operating state can then be provided by means of the biasing device and the further biasing device, wherein the respective other operating state is then set by controlling the first and/or the second flux generating device while overcoming the magnetic bias.

Analogously to embodiments with a biasing device and a further biasing device, a biasing device assigned to the first or the second flux generating device can be provided, wherein the respective other flux generating device itself provides a bias, for example in that the respective other flux generating device is formed with one or more permanent magnets. In this case, the embodiments explained above with reference to the biasing device and the further biasing device can be provided accordingly.

In general, it can be provided for the actuator assembly that the magnetic flux generated by the flux generating elements is guided to and through the actuator element by means of the pole shoe element and/or by means of one or more further pole shoe elements according to the first or the second operating state. Here, the further pole shoe elements can be adapted in terms of their shape and other configuration to the construction of the actuator assembly, for example to the number, type and assembly of flux generating elements. In particular, individual or all of the further pole shoe elements can be provided as magnetically anisotropic pole shoe elements, as explained by way of example above for various embodiments. By means of the pole shoe element and the further pole shoe elements, one or more magnetic circuits are then formed which each comprise the actuator element in order thus to provide the desired magnetic flux in the actuator element.

In the various embodiments, the actuator assembly can additionally be configured for a third operating state, in which the actuator element is penetrated by a third magnetic flux in a third direction that is perpendicular both to the first direction and to the second direction. For example, the actuator assembly can comprise a third flux generating device which is configured to generate the third magnetic flux, or in which the third magnetic flux can be generated by superposition of the magnetic flux generated by means of the third flux generating device with the magnetic flux generated by the first flux generating device and/or with the magnetic flux generated by the second flux generating device. For the third flux generating device, the embodiments explained above in connection with the first and/or the second flux generating device can be provided accordingly. Alternatively, the actuator assembly can be formed without a third flux generating device, wherein the third magnetic flux can then be generated by a targeted superposition of the magnetic flux generated by the first flux generating device and of the magnetic flux generated by the second flux generating device in addition to the first and the second magnetic flux. In connection with the third operating state, a corresponding arrangement with the pole shoe element and possibly further pole shoe elements can be provided which allows the provision of the third operating state, wherein in this connection the above embodiments with respect to the configuration of magnetic circuits in connection with two operating states can apply correspondingly.

In particular in connection with a third operating state, but also in other embodiments, the magnetically anisotropic pole shoe element and possibly further anisotropic pole shoe elements can have a lower magnetic resistance in one direction than in two directions perpendicular to the one direction and to one another. For example, the magnetically anisotropic pole shoe element and possibly further anisotropic pole shoe elements can be formed as an arrangement of rod-shaped elements with low magnetic resistance which are arranged in a matrix-like manner with respect to one another and are separated by a material with high magnetic resistance, in particular a non-magnetic material, for example epoxy resin or air.

An actuator with the actuator assembly can be provided, in particular a linear actuator. The actuator assembly can be used in particular in applications in which a linear movement must be provided and in which (passive) holding forces are desired in one or more positions. For example, an actuator comprising the actuator assembly can be used for actuating a valve, a gripping device, for example on a robot arm, or a locking device and/or in pick-and-place applications.

The embodiments explained above in connection with the actuator assembly can be provided correspondingly for the method for operating an actuator assembly.

During an operation of an actuator assembly according to the disclosure, it can be provided to control the first flux generating device and/or the second flux generating device or one or more of flux generating elements of the first and/or the second flux generating device in such a way that the flux density penetrating the actuator element changes in the first operating state and/or in the second operating state and/or that one or more further operating states occur in which the actuator element is penetrated by a further magnetic flux which runs in a direction arranged at an angle with respect to the first direction and the second direction. For example, flux generating elements of the first and/or the second flux generating device can be controlled in such a way that a magnetic flux generated thereby changes, for example by varying a current intensity with which a flux generating element formed as a coil is supplied with current. Alternatively or additionally, it can be provided to operate the first and the second flux generating device simultaneously in such a way that the magnetic fluxes are superposed in such a way that a magnetic flux penetrating the actuator element in a direction arranged at an angle with respect to the first direction and the second direction occurs. In this case, by coordinated change of the magnetic fluxes respectively generated by the first and the second flux generating device, a superposition can be achieved in such a way that the direction of a magnetic flux penetrating the actuator element rotates, in particular continuously or quasi-continuously from the first to the second direction or vice versa.

### DESCRIPTION OF EXAMPLES OF EMBODIMENTS

Further examples of embodiments are explained in more detail below with reference to figures of a drawing. Here show:

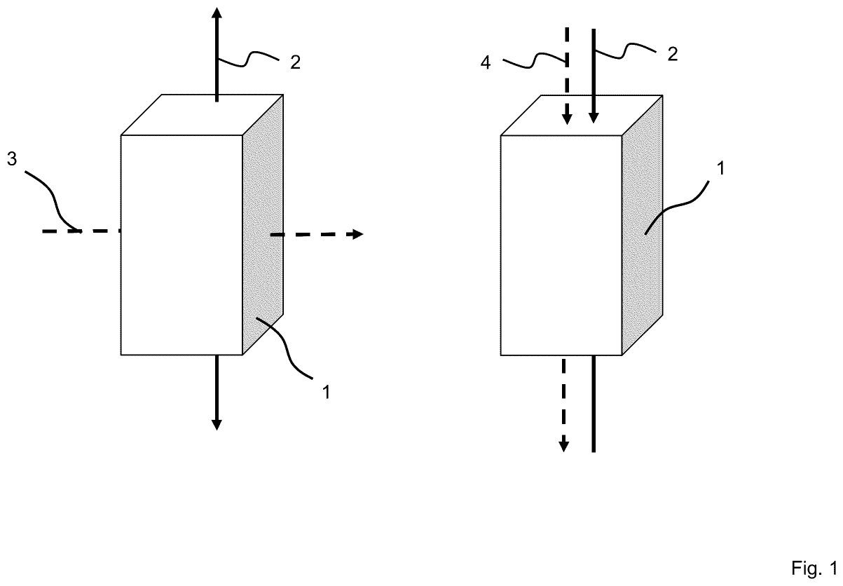

FIG. 1 a schematic illustration of an actuator element comprising a magnetic shape memory alloy in two operating states;

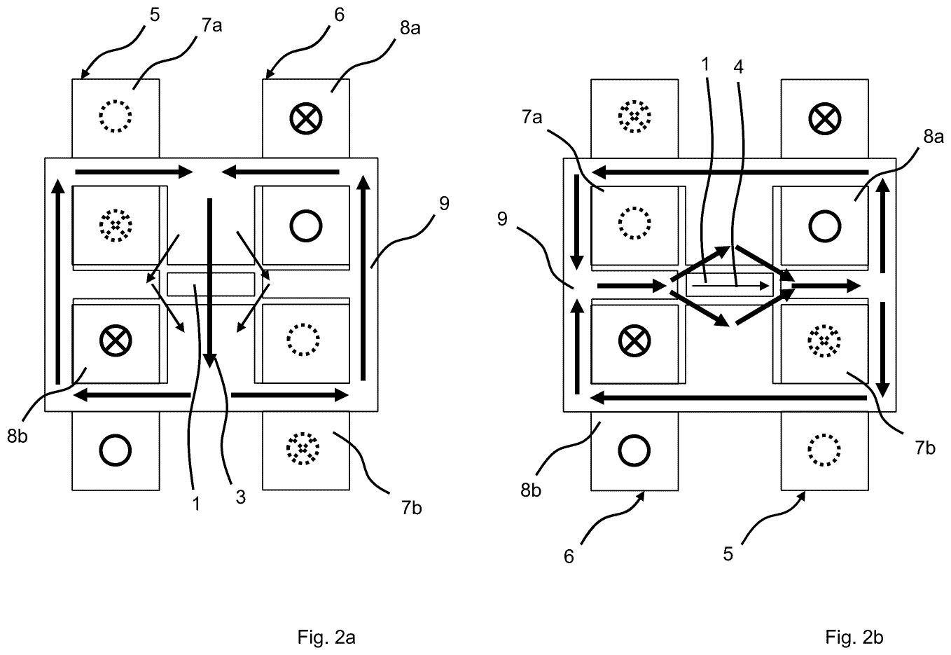

FIG. 2a a schematic illustration of a known actuator assembly in a first operating state;

FIG. 2b a schematic illustration of the known actuator assembly in a second operating state;

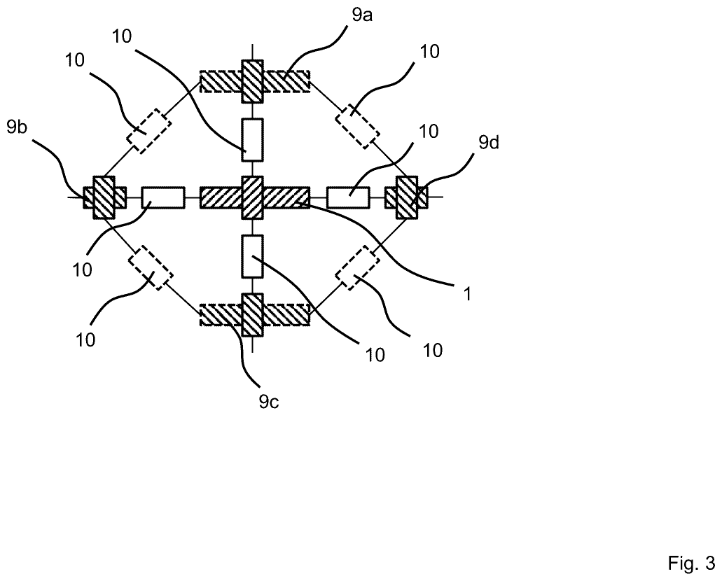

FIG. 3 a magnetic equivalent circuit of an actuator assembly;

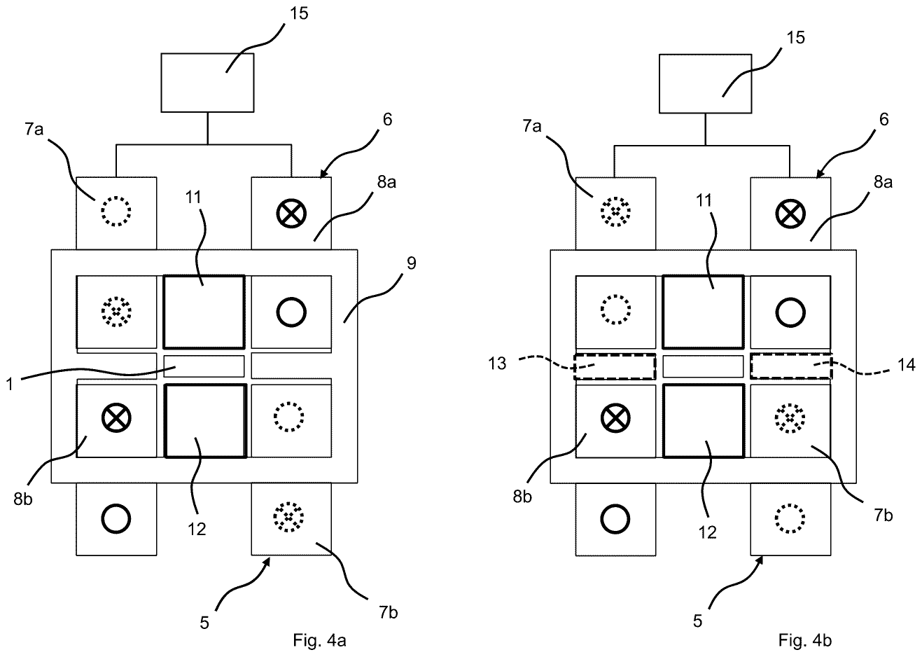

FIG. 4a a schematic illustration of an actuator assembly in a first operating state;

FIG. 4b a schematic illustration of the actuator assembly in a second operating state;

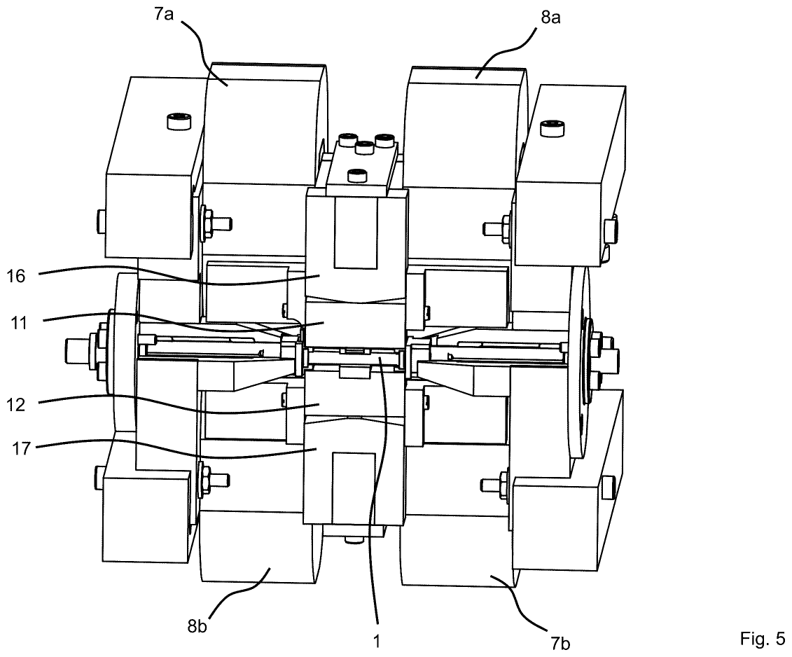

FIG. 5 a schematic illustration of a further actuator assembly;

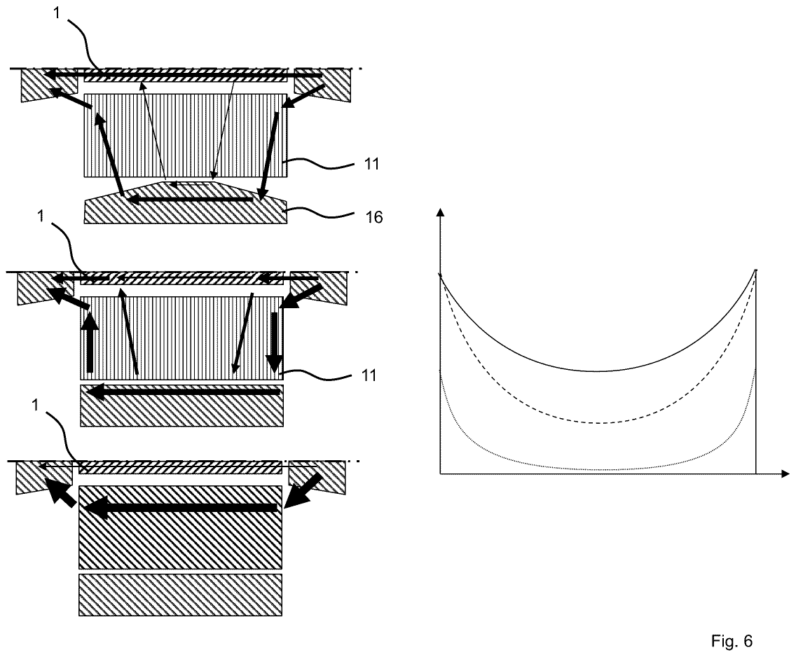

FIG. 6 a comparative illustration of magnetic fluxes in actuator assemblies;

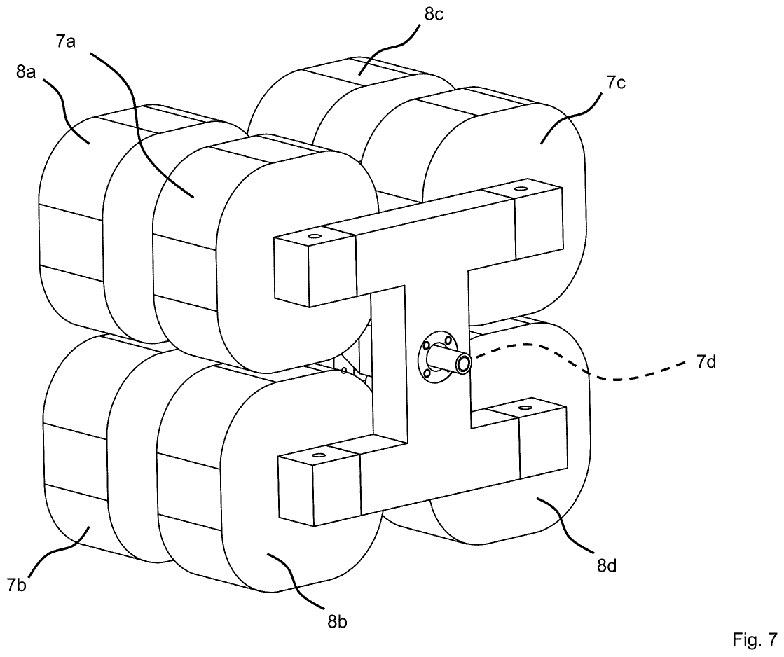

FIG. 7 a schematic illustration of an alternative actuator assembly;

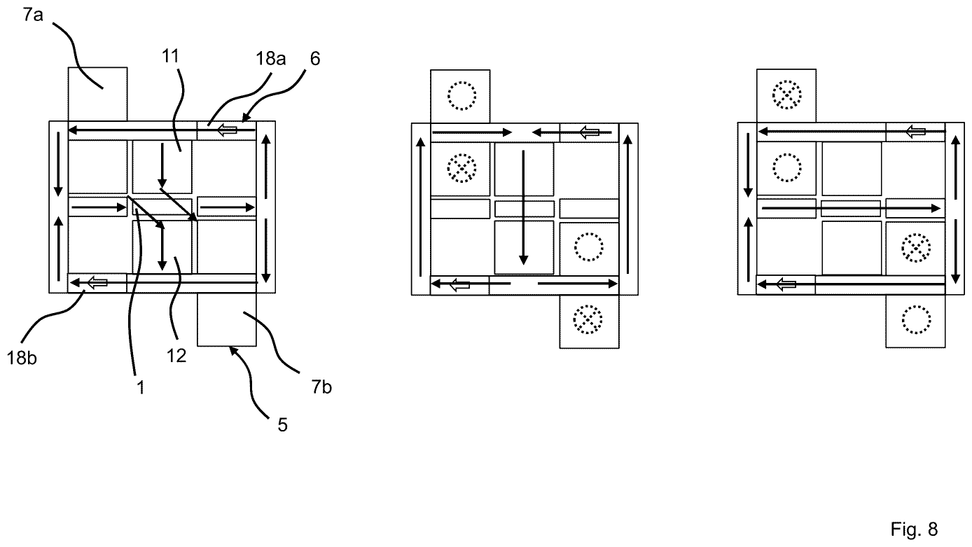

FIG. 8 schematic illustrations of operating states of an actuator assembly with a permanent magnetic flux generating device;

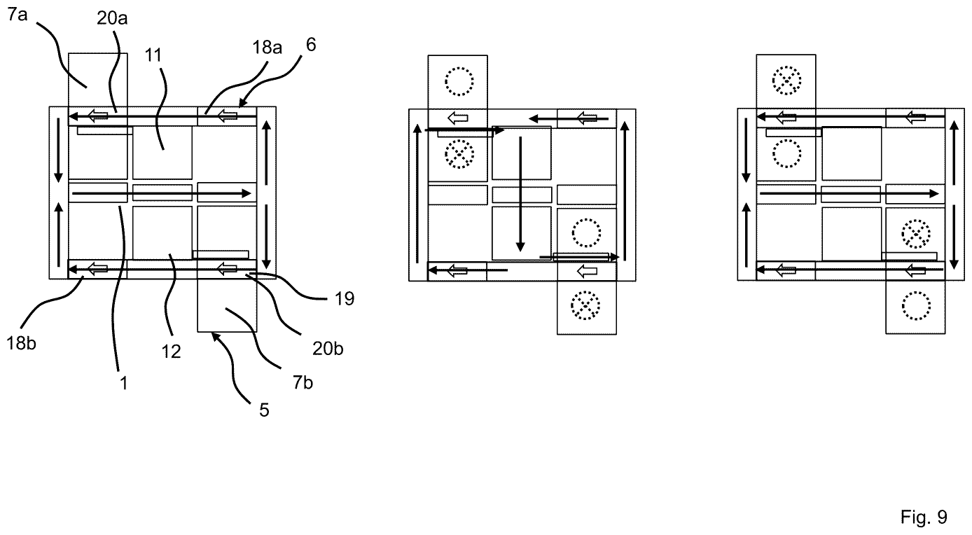

FIG. 9 schematic illustrations of operating states of an actuator assembly with a biasing device;

FIG. 10 schematic illustrations of operating states of a further actuator assembly with a biasing device;

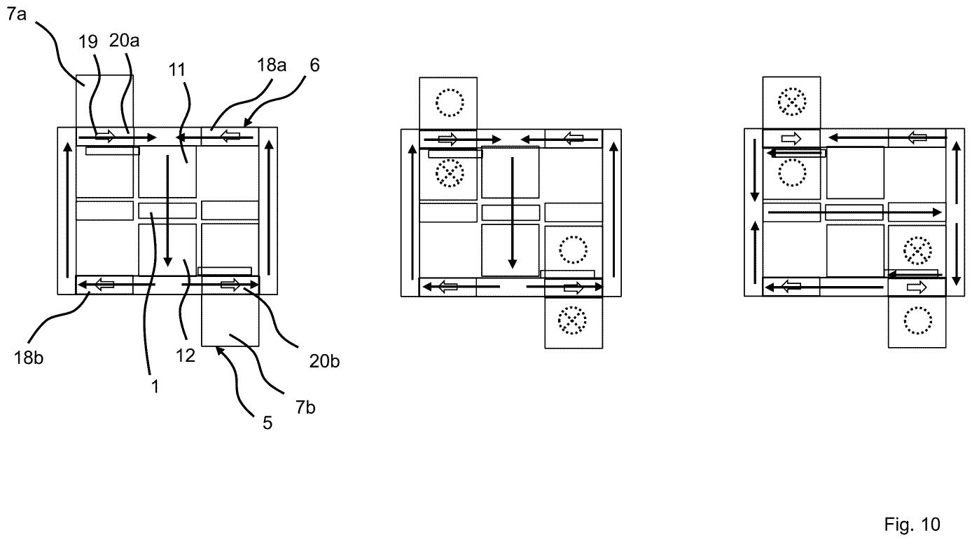

FIG. 11 schematic illustrations of operating states of an actuator assembly with an adjustable biasing device;

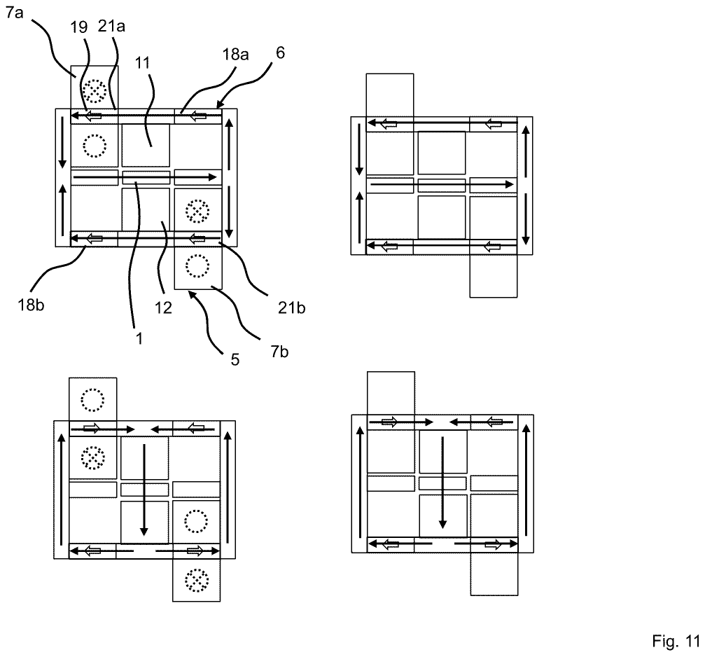

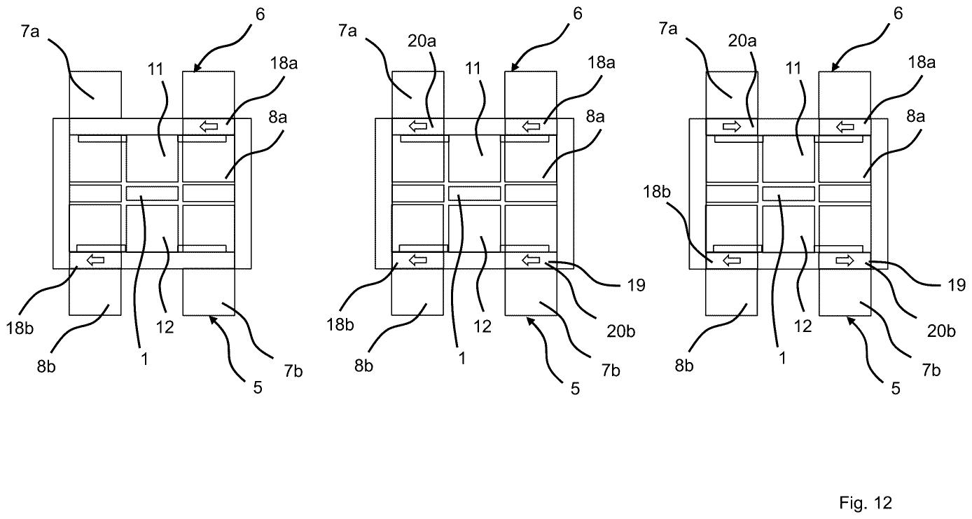

FIG. 12 schematic illustrations of alternative embodiments for actuator assemblies;

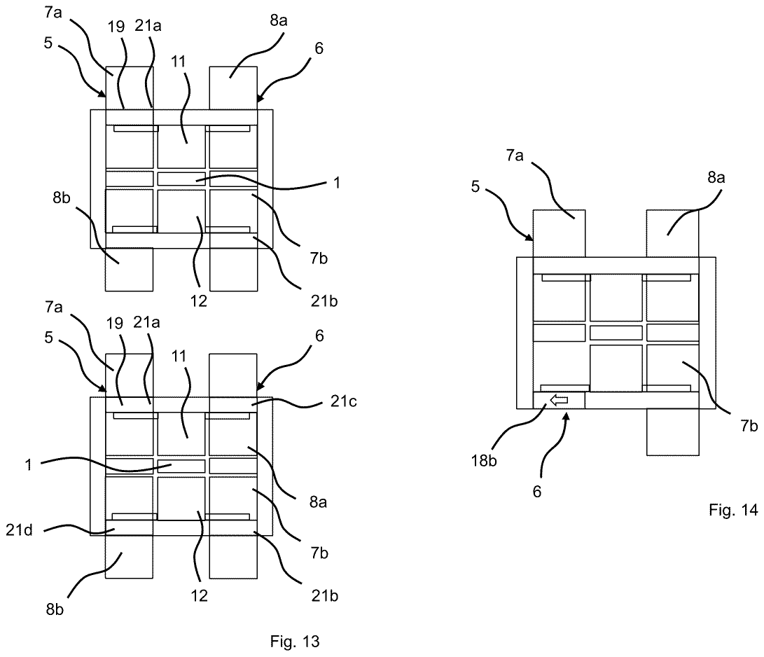

FIG. 13 schematic illustrations of further alternative embodiments for actuator assemblies;

FIG. 14 a schematic illustration of an additional embodiment of an actuator assembly;

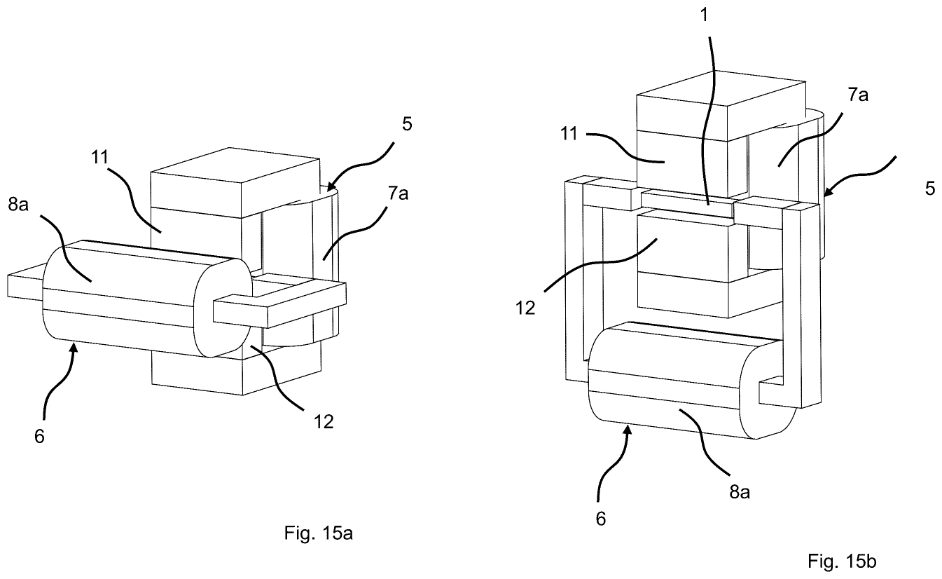

FIG. 15a a schematic illustration of an actuator assembly with independent coil sets;

FIG. 15b a schematic illustration of a further actuator assembly with independent coil sets;

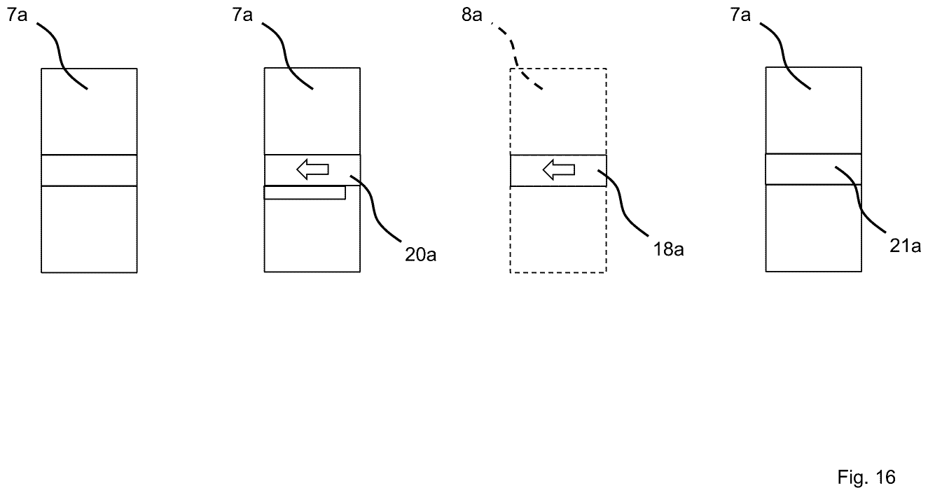

FIG. 16 schematic illustrations of various configurations of coil sets for an actuator assembly;

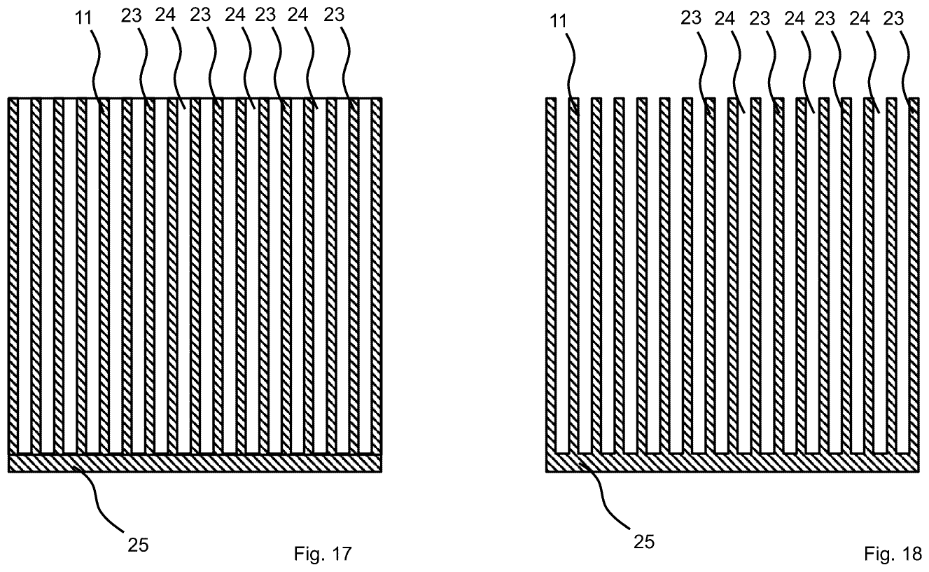

FIG. 17 a schematic illustration of a pole shoe element formed with a laminate; and

FIG. 18 a schematic illustration of a further pole shoe element formed with a laminate.

FIG. 1 shows an actuator element 1 made of a magnetic shape memory alloy (MSMA). The actuator element 1 is provided as a rod-shaped actuator element and extends along its longitudinal direction 2 when it is passed through by a (sufficiently large) first magnetic flux 3 which runs transversely with respect to the longitudinal direction 2 (elongation). If the actuator element 1 is penetrated by a second magnetic flux 4 (sufficient size) along the longitudinal direction 2, it shortens in the longitudinal direction 2 (contraction). The change in shape is caused by an orientation of magnetic elementary cells within the shape memory alloy along the magnetic field penetrating the actuator element 1. In general, a sufficiently large magnetic field in an MSMA element causes a contraction (tension) in the field direction and, correspondingly perpendicularly thereto, an elongation (pressure), wherein both force effects can be utilized. Without a magnetic field penetrating the actuator element 1, the actuator element 1 retains its shape, wherein a mechanical deformation of the actuator element is enabled when an external force overcoming the so-called twinning stress acts on the actuator element 1 and thus changes the orientation of the magnetic elementary cells by mechanical effect.

FIG. 2a shows an actuator assembly with an MSMA actuator element 1, as is known from document U.S. Pat. No. 10,581,345B 2 . The actuator assembly is formed with a first flux generating device 5 and a second flux generating device 6. The first flux generating device 5 is formed with two coils 7a, 7b and the second flux generating device 6 is formed with two coils 8a, 8b. Here, the coils 7a, 7b, 8a, 8b are oriented in a rectangular, namely square, assembly, wherein the coils 7a, 7b of the first flux generating device 5 and the coils 8a, 8b of the second flux generating device 6 each lie diagonally opposite one another, as can be seen in FIG. 2a. The coils 7a, 7b of the first flux generating device 5 are connected in series and the coils 8a, 8b of the second flux generating device 6 are connected in series.

FIG. 2a shows a first operating state of the actuator assembly, in which the actuator element 1 is penetrated by a first magnetic flux 3. FIG. 2b shows a second operating state, in which the actuator element 1 is penetrated by a second magnetic flux 4. Here, the magnetic fluxes are illustrated by arrows. The operating states are achieved by means of the current supplied to the flux generating devices 5, 6, wherein a yoke assembly 9 produced from soft iron guides the magnetic flux to the actuator element 1. In order to set the first operating state, the flux generating devices 5, 6 are supplied with current as illustrated by the current direction symbols in FIG. 2a. Here, for coils 7a, 8a/7b, 8b arranged horizontally next to one another in the illustration of FIG. 2a, an opposite direction of the generated magnetic flux is produced, with the result that the magnetic flux is guided through the center of the yoke assembly 9 in the vertical direction according to FIG. 2a and thus correspondingly to the first magnetic flux through the actuator element 1. For a change into the second operating state, the current supply direction of the first flux generating device 5 is reversed, while the current supply direction of the second flux generating device 6 remains unchanged. Thus, for coils 7a, 8a/7b, 8b arranged horizontally next to one another in the illustration of FIG. 2b, an identical direction of the generated magnetic flux is produced, with the result that the magnetic flux is guided through the center of the yoke assembly 9 in the horizontal direction according to FIG. 2b and thus correspondingly to the second magnetic flux 4 through the actuator element 1.

In the illustrations of FIGS. 2a and 2b, the strength of the magnetic flux is illustrated by the thickness of the arrows. As a result, it can be seen that, in the second operating state, a significant portion of the magnetic flux passes the actuator assembly 1 in the horizontal direction through the yoke assembly 9. A high effective loss of magnetic flux available for a deformation of the actuator element 1 is thus produced, with the result that the efficiency of the actuator assembly with respect to the second operating state is low.

FIG. 3 shows a magnetic equivalent circuit of the inner region of an actuator assembly. Here, the magnetic flux in the actuator element 1 is determined substantially by the ratios of the magnetic resistances of the surrounding sections 9a, 9b, 9c, 9d of the yoke assembly 9, of the actuator element 1 and of the air gaps 10 located therebetween.

FIGS. 4a and 4b show an actuator assembly according to the disclosure, in which, in contrast to the assembly shown in FIGS. 2a and 2b, a magnetically anisotropic pole shoe element 11 is provided. Here, FIG. 4a shows, analogously to FIG. 2a, the first operating state and FIG. 4b shows, analogously to FIG. 2b, the second operating state of the actuator assembly. The pole shoe element 11 is magnetic anisotropic in that it has a significantly lower magnetic resistance along the first direction (vertical in the illustration of FIGS. 4a and 4b) than along the second direction (horizontal in the illustration of FIGS. 4a and 4b). As a result, the first magnetic flux is effectively guided through the actuator element 1 in the first operating state. In the second operating state, the portion of the magnetic flux passing through the pole shoe element 11 is reduced by the high magnetic resistance of the pole shoe element 11 along the second direction, as a result of which the portion of the flux passing through the actuator element 1 in the second direction is increased, with the result that the efficiency of the actuator assembly in the second operating state is improved. In order to increase this effect, a second pole shoe element 12 is arranged opposite the pole shoe element. The second pole shoe element 12 is also a magnetically anisotropic pole shoe element which has a significantly lower magnetic resistance along the first direction than along the second direction.

FIG. 4b illustrates, using dashed lines, a development in which further magnetically anisotropic pole shoe elements 13, 14 are additionally provided which have a significantly higher magnetic resistance along the first direction than along the second direction and thus effectively guide the second magnetic flux through the actuator element 1 in the second operating state, while, in the first operating state, the portion of the magnetic flux passing through the pole shoe elements 13, 14 is reduced by the high magnetic resistance of the pole shoe elements 13, 14 along the first direction. In order to guide the magnetic flux, the yoke assembly can comprise further pole shoe elements (not illustrated) which can each be embodied as magnetically anisotropic or magnetically isotropic. One or both further magnetically anisotropic pole shoe elements 13, 14 can likewise be provided correspondingly in the embodiments explained below.

The actuator assembly comprises a control device 15 with which the current supply to the flux generating devices 5, 6 is controlled in order to set the first and the second operating state.

FIG. 5 shows a further actuator assembly. In comparison with the actuator assembly of FIGS. 4a and 4b, the actuator assembly of FIG. 5 comprises a flux guiding element 16 which, in the embodiment shown, is formed from soft iron. The flux guiding element 16 is formed with a wedge geometry facing the pole shoe element 11, with the result that the flux guiding element 14 touches the pole shoe element in a central region situated centrally along the second direction and an air gap is formed which increases in size along the second direction with respect to the edges of the flux guiding element 16. The magnetic resistance of the arrangement of pole shoe element 11 and flux guiding element 16 is increased by the air gap in the edge regions. As a result, the magnetic flux passing the actuator element 1 through the pole shoe element is further reduced in the second operating state. A further flux guiding element 17 with a wedge geometry is assigned to the pole shoe element 12 in an analogous arrangement.

In the actuator assembly according to FIG. 5, the axes of the coils 7a, 7b, 8a, 8b lie in one plane. The actuator element 1 is arranged offset with respect to this plane and thus eccentrically with respect to the coils 7a, 7b, 8a, 8b, but centrally with respect to the coils 7a, 7b, 8a, 8b in a projected manner onto the plane. As a result, a particularly compact construction is achieved in the illustrated assembly. In alternative embodiments, the actuator element can also lie in the plane or, in addition to the displacement out of the plane, can also be arranged eccentrically displaced in the projection onto the plane with respect to the coils 7a, 7b, 8a, 8b.

FIG. 6 illustrates the increase in efficiency achieved by using magnetically anisotropic pole shoe elements. Here, on the left-hand side of FIG. 6, the regions below an axis of symmetry in the second operating state are illustrated in each case one above the other for various embodiments of the central region of an actuator assembly. An assembly without a magnetically anisotropic pole shoe element 11 is shown at the bottom for comparison purposes. The centrally shown assembly is formed with a magnetically anisotropic pole shoe element 11. The assembly shown above comprises, in addition to a magnetically anisotropic pole shoe element 11, a wedge-shaped flux guiding element 16. The magnetic flux is illustrated by arrows, wherein a thicker arrow symbolizes a higher flux density. As can be seen from FIG. 6, the magnetic flux in an assembly without a magnetically anisotropic pole shoe element 11 can thus evade the actuator element 1 unhindered via the magnetically isotropic pole shoe element, with the result that the effective magnetic flux in the actuator element 1 is reduced, as a result of which the efficiency of the actuator assembly in the second operating state is low. In the centrally shown actuator assembly with a magnetically anisotropic pole shoe element 11, a magnetic flux along the second direction is impeded by the pole shoe element, as a result of which the flux density in the actuator element 1 is increased and the efficiency is increased. In the actuator assembly illustrated above, the air gaps achieved by the wedge geometry between pole shoe element 11 and flux guiding element 16 additionally cause an obstruction of a flux along the second direction by the flux guiding element 16, as a result of which the efficiency is further increased in the embodiment shown.

This effect is illustrated once again in FIG. 6 on the basis of a plurality of graphs. Here, the graphs show the profile of the magnetic flux density (ordinate) in the actuator element 1 along the profile of the actuator element 1 in the second direction (abscissa). It is shown that only a low magnetic flux density is achieved in the actuator element 1 for the actuator assembly illustrated at the bottom left in FIG. 6 according to the graph plotted with dotted lines. By contrast, the magnetic flux density is increased for the actuator assembly illustrated centrally at the left in FIG. 6 with a magnetically anisotropic pole shoe element 11 (graph illustrated with dashed lines). It can be seen from the graph illustrated with a solid line that, by contrast, a further increase in the magnetic flux density in the actuator element 1 is achieved by using a flux guiding element 16 with a wedge geometry in the actuator assembly illustrated at the top left, which further increase is furthermore significantly more homogeneous.

FIG. 7 shows an alternative embodiment of an actuator assembly. In comparison with the actuator assembly of FIG. 5, in the actuator assembly of FIG. 7, the first flux generating device 5 comprises four coils 7a, 7b, 7c, 7d and the second flux generating device 6 comprises four coils 8a, 8b, 8c, 8d. Here, each of the coils 7a, 7b, 8a, 8b of the actuator assembly of FIG. 5 is doubled. An even higher field strength can thereby be achieved. In further embodiments, this concept can be extended to any desired multiple of two coils.

FIG. 8 shows an actuator assembly in which, in comparison with the actuator assembly of FIGS. 4a and 4b, the second flux generating device 6 is formed with two permanent magnets 18a, 18b instead of with coils. As a result, the same state permanently results as during the current supply to the coils 8a, 8b of the second flux generating device 6 of the actuator assembly of FIGS. 4a and 4b. If the coils 7a, 7b of the first flux generating device 5 are not supplied with current, the state causing no movement and shown on the left in FIG. 8 is thus produced, in which no magnetic flux corresponding to the first or the second operating state is established in the actuator element 1. When the coils 7a, 7b of the first flux generating device 5 are supplied with current, the first operating state (FIG. 8 centrally) or the second operating state (FIG. 8 right) is then established corresponding to the current supply direction. In this way, a particularly energy-efficient actuator assembly with fewer coils can be provided.

In the actuator assembly shown in FIG. 9, in comparison with the actuator assembly of FIG. 8, a biasing device 19 assigned to the first flux generating device 5 is provided, which is formed with two permanent magnets 20a, 20b which are arranged in the interior of the respective coils 7a, 7b of the first flux generating device 5. Due to the magnetic flux generated by means of the permanent magnets 20a, 20b of the biasing device 19, a state corresponding to the current supply to the first flux generating device 5 is established without current supply. By current supply to the coils 7a, 7b of the first flux generating device 5, this state can be correspondingly reinforced (FIG. 9 right) or compensated (FIG. 9 centrally) depending on the current supply direction of a stronger current supply, so that the operating state which is different from the operating state generated by the biasing device 19 is achieved. In the interior of the coils 7a, 7b, a soft magnetic core arranged in series with an air gap is arranged parallel to the permanent magnets 20a, 20b. In the case of a compensation of the magnetic bias, the magnetic flux generated by the permanent magnets 20a, 20b is short-circuited via the respective core and air gap. In the case of short (narrow) permanent magnets 20a, 20b in the axial direction of the coils 7a, 7b, a short circuit can also be possible exclusively via an air gap arranged parallel to the respective permanent magnet 20a, 20b.

In the embodiment of FIG. 9, the actuator assembly is biased towards the second operating state by means of the biasing device 19. In contrast to this, FIG. 10 shows an embodiment in which the actuator assembly is biased towards the first operating state by means of the biasing device 19. This is achieved in that the magnetization direction of the permanent magnets 20a, 20b is reversed with respect to the actuator device of FIG. 9.

In the actuator assembly of FIG. 11, the biasing device 19 is formed with two bias elements 21a, 21b composed of magnetically semi-hard material. Magnetically semi-hard materials combine properties of soft iron and permanent magnets, since, like the latter, they have a high remanent flux density without an excitation field, but in contrast thereto can already be remagnetized at a low coercive field strength. As a result, they can be oriented by a short current supply and then maintain the flux without current. It is thus produced for the actuator assembly of FIG. 11 that the operating state set by means of current supply to the coils 7a, 7b of the first flux generating device 5 is also maintained after the end of the current supply, since the magnetically semi-hard material of the bias elements 21a, 21b has been remagnetized. Thus, in FIG. 11 at the top left, a current supply for setting the second operating state is shown, which is then maintained after the end of the current supply according to the illustration at the top right in FIG. 11. Correspondingly, FIG. 11 at the bottom left shows a current supply for setting the first operating state. This is then maintained after the end of the current supply according to the illustration at the bottom right in FIG. 11.

FIGS. 12, 13 and 14 show alternative embodiments for actuator assemblies. Here, the respective basic concept is symmetrical. A swapping of stationary (without changing the current supply or magnetic field direction between the operating states) and controlled coil pair therefore does not change the behavior for all variants and is thus always meant. Without restricting the generality, a number of further design possibilities with the known position of the static branch according to the embodiments explained above are therefore illustrated here. In alternative embodiments to the three actuator assemblies of FIGS. 8, 9 and 10, the static pair of permanent magnets 18a, 18b without coil can likewise be supplemented in all cases by additional coils 8a, 8b which can be operated in the amplification or compensation mode (cf. embodiments above). This results in the actuator assemblies shown in FIG. 12 with additional actuation combinations, wherein the assembly at the left in FIG. 12 is a further development of the assembly from FIG. 8, the assembly at the center in FIG. 12 is a further development of the assembly from FIG. 9 and the assembly at the right in FIG. 12 is a further development of the assembly from FIG. 10.

The static pair of permanent magnets 18a, 18b of the actuator assembly of FIG. 11 can likewise be replaced by coils 8a, 8b, as shown at the top in FIG. 13. At the bottom, FIG. 13 shows a further development of the actuator assembly proceeding therefrom, in which the respective core of the coils 8a, 8b is formed with magnetically semi-hard bias elements 21c, 21d.

FIG. 14 shows by way of example an actuator assembly with an asymmetry within the second flux generating device 6, which in this embodiment is formed with a coil 8a and a permanent magnet 18b.

The concepts illustrated in FIGS. 8 to 14 can be transferred correspondingly to coil assemblies differing from the illustration of FIG. 4a and 4b, for example to assemblies with eccentrically placed actuator element (cf. FIG. 5), assemblies with more than two flux generating elements per flux generating device (cf. FIG. 7) or assemblies with independent coil sets, as explained below.

FIGS. 15a and 15b show actuator assemblies in which the flux generating devices 5, 6 form independent coil sets, in which therefore the first flux generating device 5 generates the first magnetic flux 3 and the second flux generating device 6 generates the second magnetic flux 4 independently thereof. The first and second flux generating devices 5, 6 are therefore activated individually independently of one another and a superposition of the generated magnetic fields is not provided, although still possible. In the actuator assemblies of FIGS. 15a and 15b, the first flux generating device 5 is formed with a coil 7a and the second flux generating device 6 is formed with a coil 8a. In comparison with the assemblies shown in FIGS. 15a and 15b, the actuator assembly of FIG. 15a has a more compact construction, while the actuator assembly of FIG. 15b enables easier access to the MSMA actuator element 1, as a result of which, for example, simplified maintenance can be enabled. Here, the basic topology is identical for both actuator assemblies shown. The exact positioning of the coils 7a, 8a on the respective core is illustrated only by way of example and can be varied or divided as desired. By means of a third, independent coil set, the actuator assembly can be extended for a third flux direction in the actuator element corresponding to a third operating state, as explained above.

Furthermore, the use of permanent magnets or semi-hard materials for increasing efficiency is also possible for actuator assemblies with flux generating devices 5, 6 formed as independent coil sets, wherein the above embodiments in this respect apply correspondingly. Since, in the concept of the actuator assemblies shown in FIGS. 15a and 15b, a coil 7a serves exclusively for the elongation and a coil 8a serves exclusively for the contraction of the actuator element 1, the respective current supply and thus field direction plays no role. Only the amount is relevant for the desired functionality. Each of the two coils 7a, 8a with core can be supplemented by a permanent magnet 20a, as illustrated by way of example in FIG. 16 in the second illustration from the left for a coil 7a (with parallel air gap and core) (at the very left in FIG. 16 for comparison a coil 7a without modification). The permanent magnet 20a enables a bias in favor of the associated movement (contraction or elongation). A rotation of the magnet 20a by 180 leads to the same result. If both directions are biased, a balanced state without movement is again produced. The complete replacement of a coil 7a, 8a (in FIG. 16, second illustration from the right by way of example the coil 8a) by a permanent magnet 18a is likewise conceivable. In order to compensate for this effect, a very high excitation of the other coil is necessary. Further, each of the coils 7a, 8a can be supplemented by an element 21a made of a semi-hard alloy, which can be activated or compensated for by the coils. This is illustrated by way of example for the coil 7a at the very right in FIG. 16. Thus, four possibilities for modification are produced for each of the coils 7a, 8a, which can be combined with one another as desired in accordance with the respective requirements of a specific application.

FIG. 17 shows a pole shoe element 11 formed with a laminate 22. In this case, the laminate 22 consists of an arrangement of a plurality of layers in which first layers 23 of a first magnetic material, for example soft iron, and second layers 24 of a non-magnetic material, for example epoxy resin, are alternately connected to one another. For coupling a magnetic flux into the pole shoe element 11, the latter comprises a coupling element 25 made of a magnetic material, for example the first material.

FIG. 18 shows an alternative embodiment of a pole shoe element 11 formed with a laminate 22. In the embodiment of FIG. 18, the second layers 24 are formed with air which fill slots between the first layers 23. Here, the first layers are formed integrally with the coupling element 25. As an alternative to air, the second layers 24 can be formed with another gas, a gas mixture or a liquid which forms non-magnetic second layers 24 between the first layers 23.

In the case of a combination of a pole shoe element 11, 12, 13, 14 provided as a laminate 22 with a flux guiding element 16, 17 formed with a wedge shape, the weighting of the field longitudinally or transversely with respect to the actuator element 1 can be set depending on the geometry and desired behavior as a result of the dimensioning of the wedge geometry and of the anisotropic laminate. This applies both to the active case (coil as flux generating element) and to the passive case (permanent magnet as flux generating element) according to the embodiments explained above. Furthermore, the passive case can be adapted separately as a result of the selection of the magnetic bias. In combination, it can thus be made possible to set the weighting in the active and passive case independently of one another up to a certain degree. Thus, for example, a passive bias in the first direction can be combined with a pole shoe element which represents a preference of the second direction. In this way, it can be made easier in compensation operation to actively set the second operating state, while a bias with respect to the first operating state is provided.

The features disclosed in the above description, the claims and the drawing can be significant both individually and in any combination for the realization of the various embodiments.

1. Actuator assembly, comprising
an actuator element, wherein the actuator element comprises a magnetic shape memory alloy, and wherein a region of the actuator element
has a first length in a first direction, if the region is penetrated by a magnetic field in the first direction, and
has a second length in the first direction, different from the first length, if the region is penetrated by a magnetic field in a second direction that is perpendicular to the first direction;
a first flux generating device for generating a magnetic flux;
a second flux generating device for generating a magnetic flux;
a control device configured to control the first flux generating device and/or the second flux generating device according to a first operating state and a second operating state, such that
in the first operating state, the actuator element penetrated by a first magnetic flux in the first direction, and
in the second operating state, the actuator element is penetrated by a second magnetic flux in the second direction; and
a pole shoe element which is configured to guide the first magnetic flux in the first direction through the actuator element or is configured to guide the second magnetic flux in the second direction through the actuator element,
wherein the pole shoe element is provided as a magnetically anisotropic pole shoe element.

2. Actuator assembly according to claim 1, wherein
the pole shoe element is formed with a laminate;
the laminate consists of an arrangement of a plurality of layers;
the plurality of layers comprises first layers of a first material and second layers of a second material; and
in the arrangement of a plurality of layers, first layers and second layers are alternately arranged one above the other,
wherein the first material has a first permeability number, and the second material has a second permeability number which is different from the first permeability number.

3. Actuator assembly according to claim 1, wherein the pole shoe element is formed with a magnetically anisotropic material.

4. Actuator assembly according to claim 1 with a flux guiding element assigned to the pole shoe element, which is formed with a wedge shape and is arranged such that a magnetic resistance of the arrangement of pole shoe element and assigned flux guiding element in the direction of lower magnetic resistance of the pole shoe element is higher in edge regions of the arrangement of pole shoe element and assigned flux guiding element opposite along the direction of higher magnetic resistance of the pole shoe element than in a central region of the arrangement of pole shoe element and assigned flux guiding element.

5. Actuator assembly according to claim 1 with two pole shoe elements which are arranged along the first direction on opposite sides of the actuator element and are each configured to guide the first magnetic flux in the first direction through the actuator element, wherein the two pole shoe elements are provided as magnetically anisotropic pole shoe elements.

6. Actuator assembly according to claim 5 with two further pole shoe elements which are arranged along the second direction on opposite sides of the actuator element and are each configured to guide the second magnetic flux in the second direction through the actuator element.

7. Actuator assembly according to claim 6, wherein the two further pole shoe elements are provided as magnetically anisotropic pole shoe elements.

8. Actuator assembly according to claim 1, wherein the actuator element is formed as a rod-shaped actuator element which has a greater extent along a longitudinal direction which runs in the second direction than in a transverse direction which runs in the first direction.

9. Actuator assembly according to claim 1, wherein the first flux generating device and the second flux generating device each comprise at least two flux generating elements.

10. Actuator assembly according to claim 9, wherein the first flux generating device and the second flux generating device are each formed with at least two coils as flux generating elements.

11. Actuator assembly according to claim 9, wherein
the first flux generating device is formed with at least two coils as flux generating elements, and
the second flux generating device formed with at least two permanent magnets as flux generating elements.

12. Actuator assembly according to claim 1, wherein the first flux generating device and the second flux generating device each comprise a flux generating element which is formed with a coil, wherein the first flux generating device is configured to generate the first magnetic flux and the second flux generating device is configured to generate the second magnetic flux.

13. Actuator assembly according to claim 1 with a biasing device assigned to the first flux generating device or the second flux generating device, which is configured to provide as magnetic bias a magnetic flux corresponding to an operation of the first flux generating device, or the second flux generating device, respectively, when the first flux generating device and the second flux generating device are not in operation.

14. Actuator assembly according to claim 13, wherein a direction of the magnetic bias provided by means of the biasing device is adjustable by means of the first flux generating device and/or the second flux generating device.

15. Method for operating an actuator assembly, comprising the steps:
providing the actuator assembly according to at least one of the preceding claims;
controlling the first flux generating device and/or the second flux generating device for generating the first magnetic flux penetrating the actuator element in the first direction, such that the actuator element assumes a first shape; and
controlling the first flux generating device and/or the second flux generating device for generating the second magnetic flux penetrating the actuator element in the second direction, such that the actuator element assumes a second shape which is different from the first shape.
